(19) United States
(12) Patent Application Publication
(10) Pub. No.: US 2024/0357289 A1
(43) Pub. Date: Oct. 24, 2024

(54) Wireless Surround Sound System With Common Bitstream

(71) Applicant: DTS, Inc., Calabasas, CA (US)

(72) Inventors: Dannie Lau, Los Angeles, CA (US); ChunHo Lee, Calabasas, CA (US)

(73) Assignee: DTS, Inc., Calabasas, CA (US)

(21) Appl. No.: 18/684,461

(22) PCT Filed: Aug. 16, 2022
(86) PCT No.: PCT/US2022/075003

§ 371 Date: Feb. 16, 2024

Related U.S. Application Data
(60) Provisional application No. 63/234,115, filed on Aug. 17, 2021.

(51) Int. Cl. H04R 3/12; H03G 5/16; H04N 5/06

(52) U.S. Cl. CPC H04R 3/12; H03G 5/165; H04N 5/06; H04R 2420/07

(57) ABSTRACT

A wireless surround sound system can include a plurality of speakers and a source device, such as a television. The source device can decode a multichannel audio bitstream to a plurality of audio channels. The source device can combine the plurality of audio channels into a common bitstream. The source device can wirelessly send the common bitstream as a unicast simultaneously to at least some of the speakers of the plurality of speakers. The plurality of speakers can decode the common bitstream. The plurality of speakers can render audio from the decoded common bitstream. The rendered audio can correspond to a speaker configuration of the wireless surround sound system.

### CROSS-REFERENCE TO RELATED APPLICATION

This application claims the benefit of U.S. Provisional Application No. 63/234,115, filed Aug. 17, 2021, which is hereby incorporated by reference in its entirety.

### FIELD OF THE DISCLOSURE

The present disclosure relates to a wireless surround sound system.

### BACKGROUND OF THE DISCLOSURE

Wireless surround sound systems can render multi-channel audio. There is ongoing effort to improve wireless surround sound systems.

### BRIEF DESCRIPTION OF THE DRAWINGS

FIG. 1 shows a block diagram of a wireless surround sound system, in accordance with some embodiments.

FIG. 2 shows a flowchart of an example of a method for operating a wireless surround sound system, in accordance with some embodiments.

Corresponding reference characters indicate corresponding parts throughout the several views. Elements in the drawings are not necessarily drawn to scale. The configurations shown in the drawings are merely examples and should not be construed as limiting in any manner.

### DETAILED DESCRIPTION

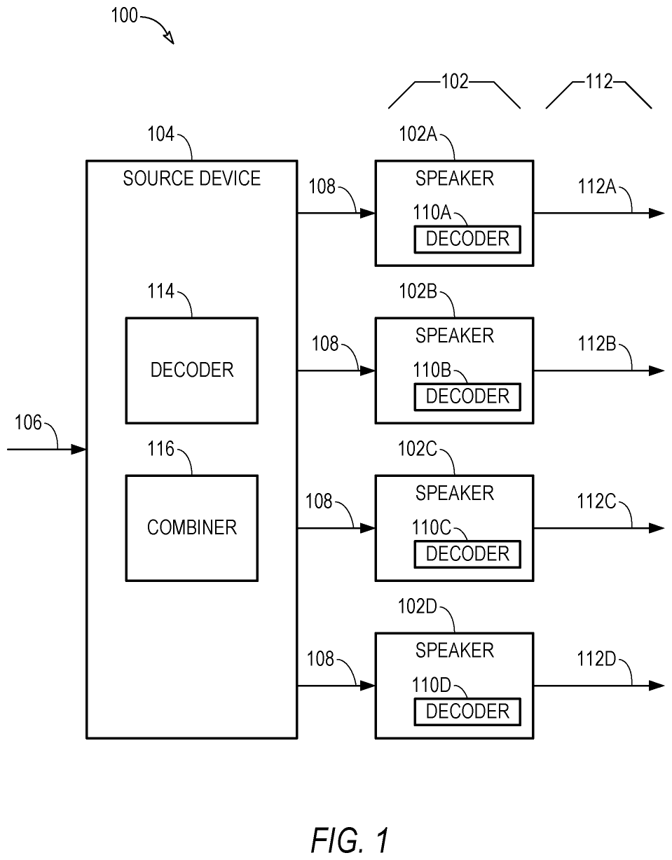

FIG. 1 shows a block diagram of an example of a wireless surround system 100, in accordance with some embodiments.

The wireless surround sound system 100 can include a plurality of speakers 102A, 102B, 102C, 102D (referred to collectively as speakers 102).

The wireless surround sound system 100 can include a source device 104, such as a television. The source device 104 can decode, with a decoder 114, a multichannel audio bitstream 106 to a plurality of audio channels, such as audio channels that include pulse-code modulation. The source device 104 can combine, with a combiner 116, the plurality of audio channels into a common bitstream 108. The source device 104 can wirelessly send the common bitstream 108 as a unicast simultaneously to at least some of the speakers 102 of the plurality of speakers 102.

The plurality of speakers 102 can include respective decoders 110A, 110B, 110C, 110D that can each decode the common bitstream 108 to extract audio from one or more audio channels of the common bitstream 108. For example, a first speaker 102A can recognize a portion of the common bitstream 108 that is directed at the first speaker 102A, such as an audio channel or a combination of audio channels from the common bitstream 108,

Each speaker 102A, 102B, 102C, 102D can render audio 112A, 112B, 112C, 112D (referred to collectively as audio 112) from an audio channel or a mix of audio from multiple audio channels from the decoded common bitstream 108. For example, the first speaker 102A can produce sound based upon the recognized portion of the common bitstream 108, such that, collectively, the plurality of speakers 102 can render sound corresponding to the speaker configuration. The rendered audio 112 can correspond to a speaker configuration of the wireless surround sound system 100, such as 5.1, 7.1, or others.

The wireless surround sound system and its components are described in greater detail below.

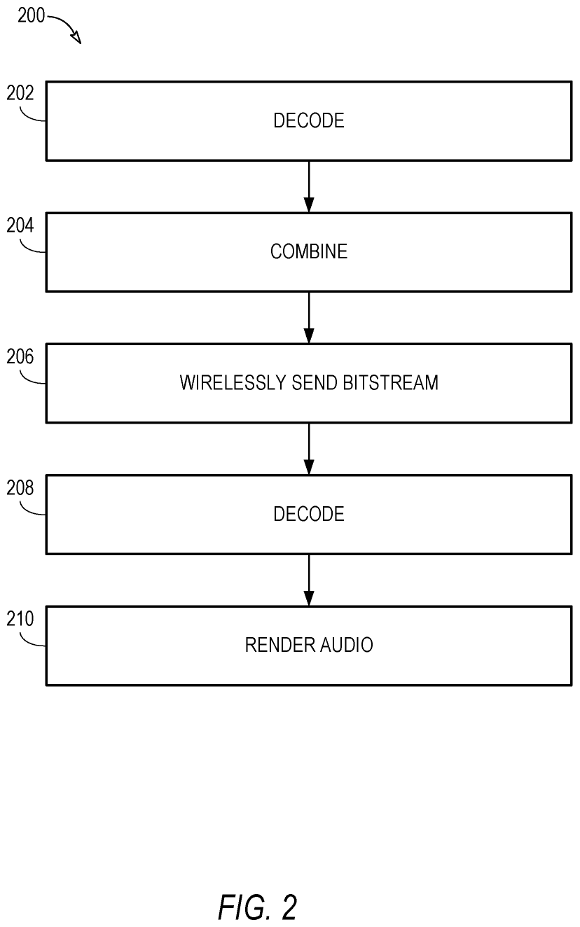

FIG. 2 shows a flowchart of an example of a method 200 for operating a wireless surround sound system, in accordance with some embodiments. The method 200 can be executed by the wireless surround sound system 100, or by another suitable wireless surround sound system. The method 200 is but one example of a method for operating a wireless surround sound system. Other suitable methods can also be used.

At operation 202, a source device can decode a multichannel audio bitstream to a plurality of audio channels.

At operation 204, a source device can combine the plurality of audio channels into a common bitstream.

At operation 206, the source device can wirelessly send the common bitstream as a unicast simultaneously to a plurality of speakers.

At operation 208, the plurality of speakers can decode the common bitstream.

At operation 210, the plurality of speakers can render audio from the decoded common bitstream. The rendered audio can correspond to a speaker configuration of the wireless surround sound system.

The method for operating the wireless surround sound system is described in greater detail below.

A flexible wireless surround sound system 100 and method can efficiently transmit audio to multiple endpoints, such as speakers 102. The wireless surround sound system 100 and method can be used to transmit audio to speakers 102 in a single room, such as for surround sound, or to transmit audio to other rooms. The wireless surround sound system 100 and method can operate over standard IP-based networking technologies, such as Wi-Fi, Ethernet, Powerline, Mocca, and others.

The source device 104, such as a television (TV), set-top box (STB), streaming device, audio/video receiver (AVR), or soundbar can decode a multichannel audio bitstream 106 to pulse-code modulation (PCM). In some examples, such as when a number of channels in the multichannel audio bitstream 106 (denoted by quantity M) is different from a number of speakers 102 in a surround sound system (denoted by quantity N), the wireless surround sound system 100 can optionally perform an up-down mix to convert the M-channel audio stream to an N-channel audio stream.

The wireless surround sound system 100 can use an intermediary codec to encode the channels of the multichannel audio bitstream 106 to a common bitstream 108. Each channel can correspond to audio directed to a particular speaker 102 or group of speakers 102. For example, a two-channel stereo audio bitstream 108 can include audio corresponding to a left channel and a right channel. In the bitstream 108, the channels are encoded in a manner such that the channels can be decoded at the endpoints. The bitstream 108 preserves a demarcation among the various channels, such that audio or data from a channel does not mix with audio or data from another channel. The bitstream 108 can included encoded packet headers, or other suitable data, to indicate how the channels are encoded in the bitstream 108. In some examples, the common bitstream 108 can be a single bitstream 108. The intermediary codec can be optimized for wireless transmission performance. The wireless surround sound system 100 can direct the common bitstream 108 to all speakers 102 in the surround sound system. The speakers 102 may be referred to as endpoints, when discussing data transmission in the wireless surround sound system 100.

There can be benefits to directing a single bitstream 108 to all speakers 102 in the surround sound system. For example, compared to a system that generates different bitstreams and sends the different bitstreams to the different speakers 102, the wireless surround sound system 100 described herein can have a reduced encoder complexity, lower computational latency, and greater bandwidth efficiency.

For a wireless surround sound system 100 that includes one or more wired channels, the wireless surround sound system 100 can reserve one or more wireless channels to wirelessly transmit the single bitstream 108 to the speakers 102 in the surround sound system. The wireless surround sound system 100 can transmit the single bitstream 108 at a specified bitrate. In general, there is a tradeoff between bandwidth and sound quality, with higher bitrates having improved sound quality at the expense of taking up more bandwidth.

The wireless surround sound system 100 can send the single bitstream 108 as a simultaneous unicast to the speakers 102. There can be benefits to sending the bitstream 108 as a simultaneous unicast. For example, compared to the system that generates different bitstreams and sends the different bitstreams to the different speakers 102, the system that sends the single bitstream 108 as a simultaneous unicast can include per-device optimized transmission coding schemes for increased bandwidth efficiency, range, and coexistence. The wireless surround sound system 100 can send the single bitstream 108 as a unicast simultaneously over multiple protocols simultaneously, such as Wi-Fi, Ethernet, Powerline, and others. For example, compared to using the Wi-Fi protocol for a pair of speakers 102, sending the single bitstream 108 as a unicast simultaneously over the Wi-Fi protocol to one speaker, such as speaker 102A, and over the Ethernet protocol to the other speaker, such as speaker 102B, can reduce the amount of Wi-Fi bandwidth used by the audio. The wireless surround sound system 100 can forward the unicast to other access points, which can extend the range of the transmission. The wireless surround sound system 100 can correct for lost packets using one or more error correction techniques, such as forward error correction (FEC), automatic repeat query (ARQ), or others.

In some examples, the wireless surround sound system 100 can route the bitstream 108 from the source device 104 directly to the speakers 102. Doing so can bypass a Wi-Fi access point, and therefore can avoid using any of the Wi-Fi bandwidth for transmitting the audio to the speakers 102. The wireless surround sound system 100 can use a direct connection technique, such as SoftAP, or Wi-Fi Direct, to route the bitstream 108 from the source device 104 directly to the speakers 102.

In some examples, each speaker 102 can decode all the channels in the bitstream 108. In some configurations, such as a speaker 102 configured as a soundbar, the speaker 102 can reproduce audio from all the channels in the bitstream 108. In other configurations, the speaker 102 can reproduce audio from only a subset of the channels in the bitstream 108. For example, a speaker 102 configured as a rear surround speaker can use only the rear surround channel in the bitstream 108. As another example, a hybrid speaker 102 that includes drivers for rear surround and rear surround height can use the rear surround channel and the rear surround height channel in the bitstream 108. The speaker 102 can discard other channels that are not used for audio playback.

In some examples, the wireless surround sound system 100 can generate multiple simultaneous unicasts. In some examples, the number of simultaneous unicasts can correspond to a number of speakers 102 or physical endpoints in the wireless surround sound system 100. The number of speakers 102 can vary across a variety of standardized or non-standardized speaker configurations, such as 5.1, 5.1.2, 5.1.4, 7.1.4, subwoofer only, hybrid, a cable replacement to a soundbar, and others.

In some examples, a speaker 102 may correspond directly to a channel in the single bitstream 108. For example, the single bitstream 108 may include a channel for a front left channel, and the speaker configuration may include a front left speaker. In other examples, a speaker 102 may not directly correspond to a channel in the single bitstream 108. For example, the speaker 102 can use audio from one or more channels of the single bitstream 108 to create a mix to be played by the speaker 102. In these examples, the wireless surround sound system 100 can use one or more virtualization techniques to create one or more virtual channels from one or more channels of the single bitstream 108. In other words, the speaker 102 can perform downmixing and/or virtual channel creation based on audio in the single bitstream 108 received from the simultaneous unicast to all the speakers 102.

For configurations in which there are speakers 102 in different rooms, the source device 104 can route the single bitstream 108 through an access point in infrastructure mode. A speaker 102 in a different room can access the single bitstream 108 through the access point. In addition, the access point can be used to direct the single bitstream 108 to one or more additional speakers 102 or endpoints, such as a headphone or a portable listening application running on a mobile device. The additional speakers 102 or endpoints can decode the single bitstream 108 to multichannel PCM audio. For additional speakers 102 or endpoints that correspond to channels that are not available in the single bitstream 108, the additional speakers 102 or endpoints can use a mixer to remix the single bitstream 108 into channels that correspond to the speakers 102 or endpoints. For example, if the single bitstream 108 includes twelve channels of audio, but the speaker 102 is a left/right stereo speaker, the speaker 102 can downmix the twelve channels to left/right stereo and render the audio as left/right stereo.

In some examples, the wireless surround sound system 100 can transmit the single bitstream 108, via a simultaneous unicast, simultaneously in a standard infrastructure mode and in a direct transmission mode. For example, the wireless surround sound system 100 can transmit the single bitstream 108 to speakers 102 in other rooms via infrastructure mode and can transmit the single bitstream 108 to speakers 102 in a single room via direct mode, such as through a SoftAP. Simultaneously transmitting via both the infrastructure mode and the direct transmission mode call can allow the wireless surround sound system 100 (or the source device 104) to supply audio to a surround sound system and simultaneously supply audio to other devices in the home to play in synchronization with one another and with the surround sound system.

In a source device 104, such as a television, a set top box, or a streaming device, a media subsystem can decode a multichannel audio bitstream 106, demultiplex the multichannel audio bitstream 106 to individual channels of digital audio, and render video and audio synchronously. For audio that is made available to a common-bitstream transmission wireless multi-room and surround system (“CBT”) synchronously to a video signal, the wireless surround sound system 100 can extract implicit audiovisual synchronization clock information from the audio stream and can transform the extracted clock information into a function of a leader audio clock of a networking platform, such as Play-Fi. In some examples, the video signal can have a known offset, which can be set dynamically or statically.

The CBT can capture audio. The captured audio can include an original audio clock, which is embedded by the media subsystem. The CBT can perform audiovisual sync disciplining on the captured audio, which can embed the Play-Fi leader clock into the audio stream to replace the original audio clock. After the wireless surround sound system 100 has run the captured audio stream through audiovisual sync disciplining, the wireless surround sound system 100 can transmit the audio stream to the speakers 102. The speakers 102 receive the audio stream as a received audio stream. The speakers 102 (also referred to as followers) can perform Play-Fi leader-follower clock synchronization to recover or construct the Play-Fi leader clock. The speakers 102 can perform follower sync disciplining on the received audio stream, which can transform the Play-Fi leader clock into a function of a local audio clock.

The source device 104 and speaker 102 can use Play-Fi leader/follower clock synchronization to synchronize their respective clocks. The speakers 102 can perform clock disciplining to recover the leader clock through a set of message exchanges with the source device 104. For devices that are at the edge of two networks, such as a TV by virtue of supporting surround sound, the devices can maintain two clock synchronization domains to support concurrent surround speakers 102 and multi-room speakers 102.

The wireless surround sound system 100 may additionally decode and process a video signal. Video processing can include advanced resolution scaling, image enhancement algorithms, and/or other routines that are computationally intensive. As a result, processing the video signal can require more processing than an audio signal. To give the processor or processors time to perform the video processing, the wireless surround sound system 100 can intentionally delay playback of the accompanying audio, so that the video and audio are played synchronously with a specified delay. In some examples, a television can specify the delay, which can vary from manufacturer to manufacturer, from model to model, and even as a single television's resolution and playback settings are changed. The television can communicate the specified delay to the speakers 102. The speakers 102 can all render audio at the specified time set by the television.

In some examples, the television can function as the source device 104 in the wireless surround sound system 100. The television can have one or more integrated (e.g., built-in) speakers 102 that can function as one or more of the speakers 102 in the wireless surround sound system 100. For example, the television's integrated speaker 102 can operate as a L+R (left plus right) channel, or a L+C+R (left plus center plus right) channel. The television can send a specified delay (or a specified latency) to other (non-integrated) speakers 102 in the wireless surround sound system 100 via the single bitstream 108. The television can report its own playback latency. The television can compensate for its own playback latency during rendering of the audio and video, to ensure that the television's audio playback is synchronized with the playback from other speakers 102 in the wireless surround sound system 100.

For configurations in which the television does not know the playback latencies of the speakers 102 or other external audio components, the wireless surround sound system 100 can perform calibration using a mobile device, such as a phone-based calibration application that utilizes time-of-flight. For example, the phone-based calibration application can connect to the television. The phone-based calibration application can perform a clock synchronization, then can cause the television to emit a test signal. The phone-based calibration application can use a microphone in the phone to listen for the test signal. The phone-based calibration application can compare a time at which the phone heard the test signal with a time at which the phone expected to hear the test signal. The comparison yields a time difference. The phone-based calibration application can report the measured time difference to the television. The television can delay or advance its audio playback to compensate for the time difference. The television can synchronize the speakers 102 based on measured playback latencies. For example, if the phone-based calibration application measured a lag in the audio path of 5 milliseconds, the TV can compensate for the lag by rendering audio earlier by 5 milliseconds.

Because speakers 102 in the wireless surround sound system 100 can access all channels in the bitstream 108, the speakers 102 can apply digital signal processing settings, such as compressors and/or limiters, in a global manner. Compared to a system in which the digital signal processing of one speaker 102 is inaccessible to another speaker 102, the wireless surround sound system 100 can avoid processing conflicts between speakers 102 that might cause audible image issues or anomalies.

The single bitstream 108 can be sent to a portable listening device or a headphone application on a mobile device. The wireless surround sound system 100 can maintain synchronization between the source device 104 and the mobile device in a manner similar to how the other speakers 102 are synchronized. The mobile device and/or the wireless surround sound system 100 can decode the audio channels from the bitstream 108. For private listening, the mobile device can be used exclusively for playback. For other uses, such as related to accessibility or hearing impairment, the mobile device can be used in conjunction with other speakers 102 in the wireless surround sound system 100.

The wireless surround sound system 100 can perform calibration of the speakers 102 with respect to a listening position, such as for time-of-flight delays and/or equalization (volume as a function of frequency). For example, the wireless surround sound system 100 can include a user interface that can accept input of a distance between the speakers 102 and listening position. In some examples, the user interface can accept a manual input of a distance value. In some examples, the user interface can use a mobile device-based application to measure an audio lag at the listening position. In some examples, a mobile device-based application can listen to a frequency test signal, such as a frequency sweep, at the listening position, determine equalization parameters from the frequency sweep, and cause the wireless surround sound system 100 to compensate for the spectral performance of the room at the listening position.

To further illustrate the system and related method disclosed herein, a non-limiting list of examples is provided below. Each of the following non-limiting examples can stand on its own or can be combined in any permutation or combination with any one or more of the other examples.

In Example 1, a wireless surround sound system comprises: a plurality of speakers; and a source device configured to decode a multichannel audio bitstream to a plurality of audio channels, combine the plurality of audio channels into a common bitstream, and wirelessly send the common bitstream as a unicast simultaneously to at least some of the speakers of the plurality of speakers, the plurality of speakers being configured to decode the common bitstream and render audio from the decoded common bitstream, the rendered audio corresponding to a speaker configuration of the wireless surround sound system.

In Example 2, the wireless surround sound system of Example 1 can optionally be configured such that the audio channels of the plurality of audio channels include pulse-code modulation.

In Example 3, the wireless surround sound system of any one of Examples 1-2 can optionally be configured such that the source device is further configured to: perform a mix to convert a first number of audio channels of the multichannel audio bitstream to a second number of audio channels corresponding to the speaker configuration of the wireless surround sound system; and combine the second number of audio channels into the common bitstream.

In Example 4, the wireless surround sound system of any one of Examples 1-3 can optionally be configured such that the source device is further configured to send the common bitstream via a first protocol to a first speaker of the plurality of speakers and send the common bitstream via a second protocol, different from the first protocol, to a second speaker of the plurality of speakers.

In Example 5, the wireless surround sound system of any one of Examples 1-4 can optionally be configured such that: a first speaker of the plurality of speakers corresponds directly to a first audio channel of the common bitstream; and the first speaker of the plurality of speakers is configured to render audio from the first audio channel.

In Example 6, the wireless surround sound system of any one of Examples 1-5 can optionally be configured such that: a first speaker of the plurality of speakers does not correspond directly to an audio channel of the common bitstream; the first speaker of the plurality of speakers is configured to create a virtual channel from one or more audio channels of the common bitstream; and the first speaker of the plurality of speakers is configured to render audio from the virtual channel.

In Example 7, the wireless surround sound system of any one of Examples 1-6 can optionally be configured such that: the first speaker is configured to access the common bitstream via an access point in an infrastructure mode; and the second speaker is configured to access the common bitstream via a direct transmission mode.

In Example 8, the wireless surround sound system of any one of Examples 1-7 can optionally be configured such that the source device comprises a television.

In Example 9, the wireless surround sound system of any one of Examples 1-8 can optionally be configured such that the television has one or more integrated speakers that are included in the plurality of speakers.

In Example 10, the wireless surround sound system of any one of Examples 1-9 can optionally be configured such that the television is configured to extract audiovisual synchronization clock information from the audio stream and transform the extracted clock information into a function of a leader audio clock of a networking platform.

In Example 11, the wireless surround sound system of any one of Examples 1-10 can optionally be configured such that the television is configured to: specify a delay; communicate the specified delay to the plurality of speakers; and render video, the plurality of speakers being further configured render the audio with the specified delay to synchronize with the video rendered by the television.

In Example 12, the wireless surround sound system of any one of Examples 1-11 can optionally be configured such that the television is configured to: measure playback latencies of the plurality of speakers using a time-of-flight application on a mobile device; and synchronize the plurality of speakers based on the measured playback latencies.

In Example 13, the wireless surround sound system of any one of Examples 1-12 can optionally be configured such that the television is configured to: measure frequency test signals rendered by the plurality of speakers using a microphone of a mobile device; determine equalization parameters for the plurality of speakers based on the measured frequency test signals; and adjust the respective spectra of the plurality of speakers using the determined equalization parameters.

In Example 14, a method for operating a wireless surround sound system comprises: decoding, with a source device, a multichannel audio bitstream to a plurality of audio channels; combining, with the source device, the plurality of audio channels into a common bitstream; wirelessly sending, with the source device, the common bitstream as a unicast simultaneously to a plurality of speakers; decoding, with the plurality of speakers, the common bitstream; and rendering, with the plurality of speakers, audio from the decoded common bitstream, the rendered audio corresponding to a speaker configuration of the wireless surround sound system.

In Example 15, the method of Example 14 can optionally further comprise: performing, with the source device, a mix to convert a first number of audio channels of the multichannel audio bitstream to a second number of audio channels corresponding to the speaker configuration of the wireless surround sound system; and combining, with the source device, the second number of audio channels into the common bitstream.

In Example 16, the method of any one of Examples 14-15 can optionally further comprise: sending, with the source device, the common bitstream via a first protocol to a first speaker of the plurality of speakers; and sending, with the source device, the common bitstream via a second protocol, different from the first protocol, to a second speaker of the plurality of speakers.

In Example 17, the method of any one of Examples 14-16 can optionally be configured such that: a first speaker of the plurality of speakers corresponds directly to a first audio channel of the common bitstream; and the first speaker of the plurality of speakers is configured to render audio from the first audio channel.

In Example 18, the method of any one of Examples 14-17 can optionally be configured such that: a first speaker of the plurality of speakers does not correspond directly to an audio channel of the common bitstream; the first speaker of the plurality of speakers is configured to create a virtual channel from one or more audio channels of the common bitstream; and the first speaker of the plurality of speakers is configured to render audio from the virtual channel.

In Example 19, the method of any one of Examples 14-18 can optionally further comprise: accessing, with a first speaker, the common bitstream via an access point in an infrastructure mode; and accessing, with a second speaker, the common bitstream via a direct transmission mode.

In Example 20, a wireless surround sound system comprises: a plurality of speakers; and a television configured to decode a multichannel audio bitstream to a plurality of audio channels that include pulse-code modulation, combine the plurality of audio channels into a common bitstream, and wirelessly send the common bitstream as a unicast simultaneously to at least some of the speakers of the plurality of speakers, each speaker of the plurality of speakers being configured to decode the common bitstream and render audio from the decoded common bitstream, the rendered audio corresponding to a speaker configuration of the wireless surround sound system.

Many other variations than those described herein will be apparent from this document. For example, depending on the embodiment, certain acts, events, or functions of any of the methods and algorithms described herein can be performed in a different sequence, can be added, merged, or left out altogether (such that not all described acts or events are necessary for the practice of the methods and algorithms). Moreover, in certain embodiments, acts or events can be performed concurrently, such as through multi-threaded processing, interrupt processing, or multiple processors or processor cores or on other parallel architectures, rather than sequentially. In addition, different tasks or processes can be performed by different machines and computing systems that can function together.

The various illustrative logical blocks, modules, methods, and algorithm processes and sequences described in connection with the embodiments disclosed herein can be implemented as electronic hardware, computer software, or combinations of both. To clearly illustrate this interchangeability of hardware and software, various illustrative components, blocks, modules, and process actions have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of this document.

The various illustrative logical blocks and modules described in connection with the embodiments disclosed herein can be implemented or performed by a machine, such as a general-purpose processor, a processing device, a computing device having one or more processing devices, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor and processing device can be a microprocessor, but in the alternative, the processor can be a controller, microcontroller, or state machine, combinations of the same, or the like. A processor can also be implemented as a combination of computing devices, such as a combination of a DSP and a microprocessor, a plurality of microprocessors, one or more microprocessors in conjunction with a DSP core, or any other such configuration.

Embodiments of the wireless surround sound system and method described herein are operational within numerous types of general purpose or special purpose computing system environments or configurations. In general, a computing environment can include any type of computer system, including, but not limited to, a computer system based on one or more microprocessors, a mainframe computer, a digital signal processor, a portable computing device, a personal organizer, a device controller, a computational engine within an appliance, a mobile phone, a desktop computer, a mobile computer, a tablet computer, a smartphone, and appliances with an embedded computer, to name a few.

Such computing devices can be found in devices having at least some minimum computational capability, including, but not limited to, personal computers, server computers, hand-held computing devices, laptop or mobile computers, communications devices such as cell phones and PDA's, multiprocessor systems, microprocessor-based systems, set top boxes, programmable consumer electronics, network PCs, minicomputers, mainframe computers, audio or video media players, and so forth. In some embodiments the computing devices will include one or more processors. Each processor may be a specialized microprocessor, such as a digital signal processor (DSP), a very long instruction word (VLIW), or other microcontroller, or can be conventional central processing units (CPUs) having one or more processing cores, including specialized graphics processing unit (GPU)-based cores in a multi-core CPU.

The process actions or operations of a method, process, or algorithm described in connection with the embodiments disclosed herein can be embodied directly in hardware, in a software module executed by a processor, or in any combination of the two. The software module can be contained in computer-readable media that can be accessed by a computing device. The computer-readable media includes both volatile and nonvolatile media that is either removable, non-removable, or some combination thereof. The computer-readable media is used to store information such as computer-readable or computer-executable instructions, data structures, program modules, or other data. By way of example, and not limitation, computer readable media may comprise computer storage media and communication media.

Computer storage media includes, but is not limited to, computer or machine readable media or storage devices such as Blu-ray discs (BD), digital versatile discs (DVDs), compact discs (CDs), floppy disks, tape drives, hard drives, optical drives, solid state memory devices, RAM memory, ROM memory, EPROM memory, EEPROM memory, flash memory or other memory technology, magnetic cassettes, magnetic tapes, magnetic disk storage, or other magnetic storage devices, or any other device which can be used to store the desired information and which can be accessed by one or more computing devices.

A software module can reside in the RAM memory, flash memory, ROM memory, EPROM memory, EEPROM memory, registers, hard disk, a removable disk, a CDROM, or any other form of non-transitory computer-readable storage medium, media, or physical computer storage known in the art. An exemplary storage medium can be coupled to the processor such that the processor can read information from, and write information to, the storage medium. In the alternative, the storage medium can be integral to the processor. The processor and the storage medium can reside in an application specific integrated circuit (ASIC). The ASIC can reside in a user terminal. Alternatively, the processor and the storage medium can reside as discrete components in a user terminal.

The phrase “non-transitory” as used in this document means enduring or long-lived”. The phrase “non-transitory computer-readable media” includes any and all computer-readable media, with the sole exception of a transitory, propagating signal. This includes, by way of example and not limitation, non-transitory computer-readable media such as register memory, processor cache and random-access memory (RAM).

The phrase “audio signal” is a signal that is representative of a physical sound.

Retention of information such as computer-readable or computer-executable instructions, data structures, program modules, and so forth, can also be accomplished by using a variety of the communication media to encode one or more modulated data signals, electromagnetic waves (such as carrier waves), or other transport mechanisms or communications protocols, and includes any wired or wireless information delivery mechanism. In general, these communication media refer to a signal that has one or more of its characteristics set or changed in such a manner as to encode information or instructions in the signal. For example, communication media includes wired media such as a wired network or direct-wired connection carrying one or more modulated data signals, and wireless media such as acoustic, radio frequency (RF), infrared, laser, and other wireless media for transmitting, receiving, or both, one or more modulated data signals or electromagnetic waves. Combinations of the any of the above should also be included within the scope of communication media.

Further, one or any combination of software, programs, computer program products that embody some or all of the various embodiments of the wireless surround sound system and method described herein, or portions thereof, may be stored, received, transmitted, or read from any desired combination of computer or machine-readable media or storage devices and communication media in the form of computer executable instructions or other data structures.

Embodiments of the wireless surround sound system and method described herein may be further described in the general context of computer-executable instructions, such as program modules, being executed by a computing device. Generally, program modules include routines, programs, objects, components, data structures, and so forth, which perform particular tasks or implement particular abstract data types. The embodiments described herein may also be practiced in distributed computing environments where tasks are performed by one or more remote processing devices, or within a cloud of one or more devices, that are linked through one or more communications networks. In a distributed computing environment, program modules may be located in both local and remote computer storage media including media storage devices. Still further, the aforementioned instructions may be implemented, in part or in whole, as hardware logic circuits, which may or may not include a processor.

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

While the above detailed description has shown, described, and pointed out novel features as applied to various embodiments, it will be understood that various omissions, substitutions, and changes in the form and details of the devices or algorithms illustrated can be made without departing from the scope of the disclosure. As will be recognized, certain embodiments of the inventions described herein can be embodied within a form that does not provide all of the features and benefits set forth herein, as some features can be used or practiced separately from others.

What is claimed is:

1. A wireless surround sound system, comprising:
a plurality of speakers; and
a source device configured to decode a multichannel audio bitstream to a plurality of audio channels, combine the plurality of audio channels into a common bitstream, and wirelessly send the common bitstream as a unicast simultaneously to at least some of the speakers of the plurality of speakers,
the plurality of speakers being configured to decode the common bitstream and render audio from the decoded common bitstream, the rendered audio corresponding to a speaker configuration of the wireless surround sound system.

2. The wireless surround sound system of claim 1, wherein the audio channels of the plurality of audio channels include pulse-code modulation.

3. The wireless surround sound system of claim 1, wherein the source device is further configured to:
perform a mix to convert a first number of audio channels of the multichannel audio bitstream to a second number of audio channels corresponding to the speaker configuration of the wireless surround sound system; and
combine the second number of audio channels into the common bitstream.

4. The wireless surround sound system of claim 1, wherein the source device is further configured to send the common bitstream via a first protocol to a first speaker of the plurality of speakers and send the common bitstream via a second protocol, different from the first protocol, to a second speaker of the plurality of speakers.

5. The wireless surround sound system of claim 1, wherein:
a first speaker of the plurality of speakers corresponds directly to a first audio channel of the common bitstream; and
the first speaker of the plurality of speakers is configured to render audio from the first audio channel.

6. The wireless surround sound system of claim 1, wherein:
a first speaker of the plurality of speakers does not correspond directly to an audio channel of the common bitstream;
the first speaker of the plurality of speakers is configured to create a virtual channel from one or more audio channels of the common bitstream; and
the first speaker of the plurality of speakers is configured to render audio from the virtual channel.

7. The wireless surround sound system of claim 1, wherein:
the first speaker is configured to access the common bitstream via an access point in an infrastructure mode; and
the second speaker is configured to access the common bitstream via a direct transmission mode.

8. The wireless surround sound system of claim 1, wherein the source device comprises a television.

9. The wireless surround sound system of claim 8, wherein the television has one or more integrated speakers that are included in the plurality of speakers.

10. The wireless surround sound system of claim 8, wherein the television is configured to extract audiovisual synchronization clock information from the audio stream and transform the extracted clock information into a function of a leader audio clock of a networking platform.

11. The wireless surround sound system of claim 8, wherein the television is configured to:
specify a delay;
communicate the specified delay to the plurality of speakers; and
render video,
the plurality of speakers being further configured render the audio with the specified delay to synchronize with the video rendered by the television.

12. The wireless surround sound system of claim 8, wherein the television is configured to:
measure playback latencies of the plurality of speakers using a time-of-flight application on a mobile device; and
synchronize the plurality of speakers based on the measured playback latencies.

13. The wireless surround sound system of claim 8, wherein the television is configured to:
measure frequency test signals rendered by the plurality of speakers using a microphone of a mobile device;
determine equalization parameters for the plurality of speakers based on the measured frequency test signals; and
adjust the respective spectra of the plurality of speakers using the determined equalization parameters.

14. A method for operating a wireless surround sound system, the method comprising:
decoding, with a source device, a multichannel audio bitstream to a plurality of audio channels;
combining, with the source device, the plurality of audio channels into a common bitstream;
wirelessly sending, with the source device, the common bitstream as a unicast simultaneously to a plurality of speakers;
decoding, with the plurality of speakers, the common bitstream; and
rendering, with the plurality of speakers, audio from the decoded common bitstream, the rendered audio corresponding to a speaker configuration of the wireless surround sound system.

15. The method of claim 14, further comprising:
performing, with the source device, a mix to convert a first number of audio channels of the multichannel audio bitstream to a second number of audio channels corresponding to the speaker configuration of the wireless surround sound system; and
combining, with the source device, the second number of audio channels into the common bitstream.

16. The method of claim 14, further comprising:
sending, with the source device, the common bitstream via a first protocol to a first speaker of the plurality of speakers; and
sending, with the source device, the common bitstream via a second protocol, different from the first protocol, to a second speaker of the plurality of speakers.

17. The method of claim 14, wherein:
a first speaker of the plurality of speakers corresponds directly to a first audio channel of the common bitstream; and
the first speaker of the plurality of speakers is configured to render audio from the first audio channel.

18. The method of claim 14, wherein:
a first speaker of the plurality of speakers does not correspond directly to an audio channel of the common bitstream;
the first speaker of the plurality of speakers is configured to create a virtual channel from one or more audio channels of the common bitstream; and
the first speaker of the plurality of speakers is configured to render audio from the virtual channel.

19. The method of claim 14, further comprising:
accessing, with a first speaker, the common bitstream via an access point in an infrastructure mode; and
accessing, with a second speaker, the common bitstream via a direct transmission mode.

20. A wireless surround sound system, comprising:
a plurality of speakers; and
a television configured to decode a multichannel audio bitstream to a plurality of audio channels that include pulse-code modulation, combine the plurality of audio channels into a common bitstream, and wirelessly send the common bitstream as a unicast simultaneously to at least some of the speakers of the plurality of speakers,
each speaker of the plurality of speakers being configured to decode the common bitstream and render audio from the decoded common bitstream, the rendered audio corresponding to a speaker configuration of the wireless surround sound system.
